(19) United States
(12) Patent Application Publication
(10) Pub. No.: US 2025/0331361 A1
(43) Pub. Date: Oct. 23, 2025

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yanyang SHANG, Beijing (CN); Zhenglong YAN, Beijing (CN); Shuo LI, Beijing (CN); Zhu WANG, Beijing (CN)

(21) Appl. No.: 18/853,054

(22) PCT Filed: Jan. 2, 2024
(86) PCT No.: PCT/CN2024/070036

§ 371 Date: Sep. 30, 2024

(30) Foreign Application Priority Data
Jan. 3, 2023 (CN) 202310003823.9

(51) Int. Cl. H10K 59/121; H10K 59/122; H10K 59/80

(52) U.S. Cl. CPC H10K 59/121; H10K 59/122; H10K 59/872

(57) ABSTRACT

A display panel includes a substrate, a pixel structure located in a display region of the substrate, and a barrier dam located in a non-display area of the substrate. The pixel structure includes a pixel circuit layer, at least one planarization layer, a black pixel definition layer and a photo spacer, which are sequentially stacked; and the barrier dam includes a plurality of barrier film layers, and the plurality of barrier film layers and some film layers in the planarization layer and the photo spacer, which are included in the pixel structure, are located on the same layer, that is, the barrier dam may be made of the planarization layer and the photo spacer.

### CROSS-REFERENCE TO RELATED APPLICATION

The present disclosure is a US national stage of international application No. PCT/CN2024/070036, filed on Jan, 2, 2024, which is based on and claims priority to Chinese Patent Application No. 202310003823.9, filed on January 3, 2023 and entitled “DISPLAY PANEL AND DISPLAY APPARATUS”, the disclosures of which are incorporated herein by reference in their entireties.

### TECHNICAL FIELD

The present disclosure relates to the field of display technologies, in particular to a display panel and a display apparatus.

### BACKGROUND ART

With the development of display technologies, a barrier dam is often arranged in a non-display region of a substrate in a display panel at present to block external water vapor from invading a display region of the substrate, thereby protecting the display region

In related technologies, a barrier dam located in a non-display region generally includes a plurality of planarization (PLN) layers, a pixel definition layer (PDL) and a photo spacer (PS). which are sequentially stacked in a direction away from the substrate, where the PS may also be referred to as a PS layer. In the traditional display panel that includes a polarizer (POL), a PDL is a conventional PDL that is semi-transparent. In a non-traditional POL-less display panel, a PDL is a black pixel definition layer (BPDL) with a black performance.

However, due to a poor bending performance of BPDL compared with the conventional PDL, the current barrier dam cannot be well applied to different types of display products.

### SUMMARY OF THE INVENTION

A display panel and a display apparatus are provided. The technical solutions are summarized as follows.

In an aspect, a display panel is provided. The display panel includes:
a substrate, having a display region and a non-display region that at least partially surrounds the display region;
a plurality of pixel structures, where the plurality of pixel structures is located on one side of the substrate and in the display region, each pixel structure includes a PDL, at least one PLN layer, a BPDL and a PS layer which are sequentially stacked in a direction away from the substrate, the BPDL has a plurality of first openings arranged at intervals along a bearing surface parallel to the substrate, and each pixel structure further includes a light-emitting element located in each first opening; and
a plurality of barrier dams. where the plurality of barrier dams is located on one side of the substrate and in the non-display region, the plurality of barrier dams is arranged at intervals in a direction away from the display region, each barrier dam includes a plurality of barrier film layers sequentially stacked in a direction away from the substrate, and the plurality of barrier film layers is located on a same layer as a part of film layers in the at least one PLN layer and the PS layer.

Optionally, among the plurality of barrier dams, a barrier dam close to the display region has a width less than that of a barrier dam away from the display region; and/or, the barrier dam close to the display region has a height less than that of the barrier dam away from the display region, and
where direction of the width is parallel to the bearing surface of the substrate, and a direction of the height is perpendicular to the bearing surface of the substrate.

Optionally, the substrate also has a binding region that is located on one side of the non-display region away from the display region and is adjacent to the non-display region, and
in each of the plurality of barrier dams, a first portion close to the binding region has a height less than that of a second portion away from the binding region.

Optionally, the substrate is rectangular and has a first frame, a second frame, a third frame and a fourth frame:
the non-display region surrounds the display region, and each of the plurality of barrier dams located in the non-display region surrounds the display region, and the binding region is located on one side of the fourth frame; and
in each of the plurality of barrier dams, the first portion is located on one side of the fourth frame, the second portion is located on one side of the first frame, the second frame, the third frame and the fourth frame, and a part of the second portion that is located on one side of the fourth frame is located outside the first portion.

Optionally, widths of the plurality of barrier film layers included in the first portion and widths of the plurality of barrier film layers included in the second portion decrease sequentially in a direction close to the substrate, respectively: and, in each two adjacent barrier film layers, an orthographic projection of one barrier film layer away from the substrate on the substrate covers an orthographic projection of one barrier film layer close to the substrate on the substrate.

Optionally, central axes of the plurality of barrier film layers included in the first portion are collinear, central axes of the plurality of barrier film layers included in the second portion are collinear, and the central axes of the first portion are collinear with the central axes of the second portion.

Optionally, a number of the barrier film layers included in the first portion is less than a number of the barrier film layers included in the second portion.

Optionally, the plurality of barrier film layers included in the first portion belongs to the barrier film layers among the plurality of barrier film layers included in the second portion.

Optionally, in a part of barrier dams among the plurality of barrier dams, a barrier film layer away from the substrate among the plurality of barrier film layers included in the first portion is the same as a barrier film layer away from the substrate among the plurality of barrier film layers included in the second portion; and in other part of the barrier dams, a barrier film layer away from the substrate among the plurality of barrier film layers included in the first portion is different from a barrier film layer away from the substrate among the plurality of barrier film layers included in the second portion.

Optionally, if the widths of the plurality of barrier film layers included in the first portion and the widths of the plurality of barrier film layers included in the second portion all decrease sequentially in a direction close to the substrate, respectively, and the plurality of barrier film layers included in the first portion belongs to the barrier film layers among the plurality of barrier film layers included in the second portion, for each of the other part of the barrier dams, the barrier dam further includes a transition region between the first portion and the second portion;
in the transition region, among the plurality of barrier film lavers included in the second portion, a target film layer is transitionally widened to be equal to a width of the barrier dam, and the target film layer is used as a barrier film layer, away from the substrate, among the plurality of barrier film layers included in the first portion; and
among the plurality of barrier film layers included in the second portion, an orthographic projection of a barrier film layer away from the substrate on the substrate covers an orthographic projection of the transition region on the substrate.

Optionally, for various sides of the target film layer in the transition region, widening angles are the same and all less than 90 degrees; and/or, increased widths are the same.

Optionally, the display panel includes a first barrier dam and a second barrier dam which are arranged at intervals in a direction away from the display region, where
in the first barrier dam, the first portion includes two barrier film layers, and the second portion includes three barrier film layers; and
in the second barrier dam, the first portion includes two barrier film layers, and the second portion includes four barrier film layers.

Optionally, the pixel structure includes a first PLN layer, a second PLN layer and a third PLN layer that are sequentially stacked in a direction away from the substrate;
in the first barrier dam, two barrier film layers included in the first portion are located on a same layer as the second PLN layer and the PS layer, respectively; three barrier film layers included in the second portion are located on a same layer as the second PLN layer, the third PLN layer and the PS layer, respectively; and
in the second barrier dam, two barrier film layers included in the first portion are located on a same layer as the first PLN layer and the second PLN layer, respectively; four barrier film layers included in the second portion are located on a same layer as the first PLN layer, the second PLN layer, the third PLN layer and the PS layer, respectively. Optionally, the display panel further includes:
an encapsulation layer, a BM layer and an overcoat layer that are located on one side of the BPDL away from the substrate and are sequentially stacked in a direction away from the substrate, where the BM layer has a plurality of second openings that is in a one-to-one correspondence with the plurality of first openings; and
a filter layer, where the filter layer is located in each of the second openings, and a color of the filter layer in each second opening is the same as that of the light-emitting element in a corresponding first opening.

In another aspect, a display apparatus is provided. The display apparatus includes a driving circuit and a display panel as described in the above aspect, and
where the driving circuit is electrically connected to the display panel and is configured to drive the display panel to emit light.

### BRIEF DESCRIPTION OF THE DRAWINGS

To describe the technical solutions in the embodiments of the present invention more clearly, the following briefly introduces the accompanying drawings required for describing the embodiments. Apparently, the accompanying drawings in the following description show merely some embodiments of the present invention, and a person of ordinary skill in the art may still derive other drawings from these accompanying drawings without paying creative efforts, in which:

FIG. 1 is a schematic structural diagram of a display panel provided by an embodiment of the present disclosure;

FIG. 2 is a sectional view of a display panel provided by an embodiment of the present disclosure;

FIG. 3 is a schematic structural diagram of another display panel provided by an embodiment of the present disclosure;

FIG. 4 is a schematic structural diagram of yet another display panel provided by an embodiment of the present disclosure:

FIG. 5 is a schematic structural diagram of another display panel provided by an embodiment of the present disclosure;

FIG. 6 is a top view of a barrier dam in a display panel provided by an embodiment of the present disclosure;

FIG. 7 is a sectional view of a barrier dam in a display panel provided by an embodiment of the present disclosure in each direction;

FIG. 8 is an enlarged top view of a barrier dam in a display panel provided by an embodiment of the present disclosure; and

FIG. 9 is a schematic structural diagram of a display apparatus provided by an embodiment of the present disclosure.

### DETAILED DESCRIPTION

In order to make the objectives, technical schemes and advantages of the present disclosure clearer, a further detailed description will be made to the embodiments of the present disclosure below with reference to the accompanying drawings.

A non-traditional POL-less display panels includes, for example, a color on encapsulation (COE) display panel in which a color filter layer is integrated on an encapsulation layer. At present, on the basis of considering the improvement of optical performances of a product, a PDL and a PS layer that have light transmission performances are often prepared through a mask in the traditional display panel including polarizers, while a BPDL and a PS layer are often prepared through two masks in a polarizer-less display panel of the COE display panel. In addition, compared with the traditional display panel including polarizers, the COE display panel further includes a PLN layer located on one side of an anode of a light-emitting element close to the substrate. This PLN layer is mainly used to improve the flatness of the anode, thereby further indirectly improving the optical performances of the display panel.

Due to the addition of a carbon black additive to a substrate material of the BPDL, the bending performance and adhesiveness of the BPDL are relatively poor compared with the traditional PDL. In a foldable COE product, the bending performance of a material is very important, so it can be seen in combination with the background technology that the setting of the BPDL will lead to the inability to continue to reliably form a barrier dam. In other words, the characteristics of the BPDL make it no longer suitable for the design of the barrier dam.

For this purpose, an embodiment of the present disclosure provides a design of a barrier dam, which may be adapted to different types of display products. That is, an embodiment of the present disclosure may provide a brand-new barrier dam design for a foldable COE display product.

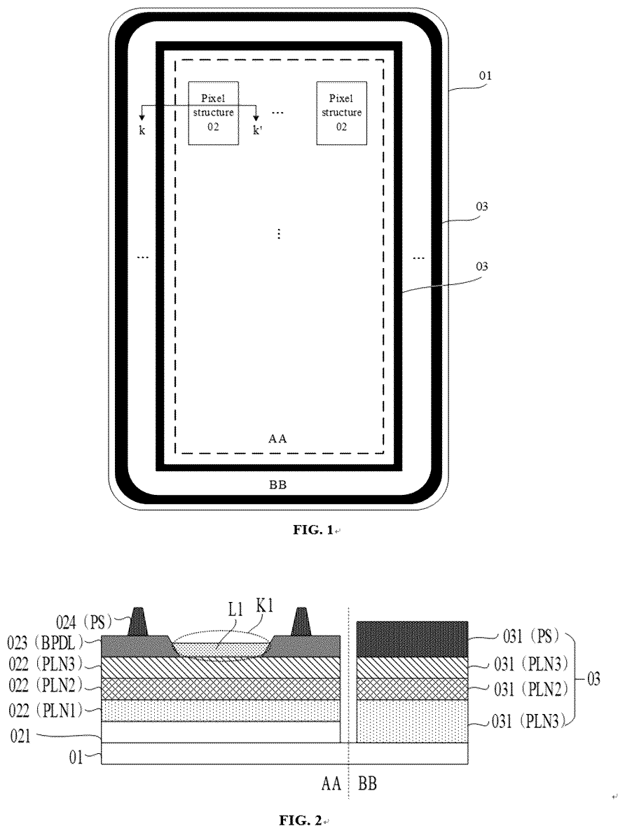

FIG. 1 is a schematic structural diagram of a display panel provided by an embodiment of the present disclosure. As shown in FIG. 1, the display panel includes a substrate 01.

The substrate 01 has a display region AA and a non-display region BB that at least partially surrounds the display region AA. For example, referring to FIG. 1, in the substrate 01 as shown, the non-display region BB surrounds the display region AA. Of course, in some other embodiments, the non-display region BB may also partially surround the display region AA. For example, the non-display region BB may be adjacent to the display region AA and be located on a left side of the display region AA. Of course, the non-display region BB is also not limited to be located on the left side of the display region AA, for example, it may also be located on an upper side of the display region AA.

It should be noted that an area of the display region AA is generally much larger than an area of the non-display region BB. The accompanying drawings are only schematic descriptions, and do not limit the area of the display region AA and the area of the non-display region BB.

Continuing with reference to FIG. 1, the display panel described in the embodiment of the present disclosure further includes a plurality of pixel structures 02 located on one side of the substrate 01 and in the display region AA and a plurality of barrier dams 03 located on one side of the substrate 01 and in the non-display region BB. The plurality of barrier dams 03 is arranged at intervals in a direction away from the display region AA. The plurality of barrier dams 03 may be used as barrier walls for subsequent encapsulation to protect the display region AA.

Based on the structure shown in FIG. 1, FIG. 2 shows a sectional view of a display panel in a kk′ direction. Referring to FIG. 2, it can be seen that each pixel structure 02 includes a pixel circuit layer 021, at least one PLN layer 022, a BPDL 023 and a PS layer 024 that are sequentially stacked in a direction away from the substrate 01. The BPDL 023 has a plurality of first opening K1 that is arranged at intervals along a bearing surface parallel to the substrate 01. The pixel structure 02 further includes a light-emitting element L1 located in each first opening K1. In other words, the light-emitting elements L1 which are located in different first openings K1 can be separated by the BPDL 023. It should be noted that FIG. 2 only schematically shows one first opening K1 and three PLN layers 022, which are labeled as PLN1, PLN2 and PLN3, respectively.

Continuing with reference to FIG. 2, it can also be seen that each barrier dam 03 includes a plurality of barrier film layers 031 that is sequentially stacked in a direction away from the substrate 01. The plurality of barrier film layers 031 is located on a same layer as a part of film layers in the plurality of PLN layers 022 and the PS layer 024.

It should be noted that “located on the same layer” may refer to a layer structure which is formed by first forming a film layer, which is used for forming a specific pattern, using the same film-forming process, and then patterning this film layer using a same mask plate through a primary composition process. Depending on different specific patterns, the primary composition process includes multiple exposures, development or etching processes, while the specific pattern in the resulting layer structure may be continuous or discontinuous. That is, a plurality of elements, components, structures and/or portions located on the “same layer” are composed of the same material and formed through the same compositional process In this way, the manufacturing process and the manufacturing cost can be saved, and the manufacturing efficiency can be accelerated.

That is, in the embodiment of the present disclosure, each barrier dam 03 may include a plurality of barrier film layers 031 formed by a part of film layers in the at least one PLN layer 022 and the PS layer 024. In addition, it should be noted that each barrier dam 03 may include a different barrier film layer 031. Because the materials for the PLN layer 022 and the PS layer 024 are generally organic materials, the barrier film lavers 031 included in the barrier dam 03 may also be referred as organic film layers.

For example, referring to FIG. 2, the barrier dam 03 as shown includes four barrier film layers 031. The four barrier film layers 031 are located on the same layer as the three PLN layers 022 (PLN1, PLN2 and PLN3) and the PS layer 024 included in the pixel structure 02, respectively. In other words, the barrier dam 03 includes three PLN layers 022 and one PS layer 024. In some embodiments, the other barrier dam 03 may include three barrier film layers 031, which are respectively located on the same layer as the three PLN layers 022, or are located on the same layer as two PLN layers 022 and one PS layer 024, respectively. Here is only a schematic description for the same-layer relationship, but does not limit the choice for the film lavers.

Because the barrier film layers 031 included in the barrier dam 03 as described in the embodiment of the present disclosure are located on the same layer as a part of film layers in the PLN layers 022 and the PS layer 024, but not on the same layer as the BPDL 023. That is, the barrier dam 03 is not prepared by using the PDL, so the problem that the BPDL 023 is not suitable for the preparation of the barrier dam 03 in a folded product due to a poor bending performance can be solved. In other words, the barrier dam 03 provided by the embodiment of the present disclosure may be applied to various display products that can be folded or not be folded, and is not limited by the material for the PDL.

In summary, an embodiment of the present disclosure provides a display panel. The display panel includes a substrate, a pixel structure located on a display region of the substrate, and a barrier dam located in a non-display region of the substrate. The pixel structure includes a pixel circuit layer, at least one PLN layer, a BPDL and a PS layer that are sequentially stacked. The barrier dam includes a plurality of barrier film layers. The plurality of barrier film layers is located on the same layer as a part of film layers in the PLN layers and the PS layer included in the pixel structure. That is, the barrier dam may be prepared by using the PLN layers and the PS layer that have a good bending performance, without using the BPDL having a poor bending performance. In this way, the problem that the BPDL cannot be applied to the preparation of barrier dams in folded products due to the poor bending performance can be solved. The barrier dam in the display panel provided by the embodiment of the present disclosure may be well applied to different types of display products.

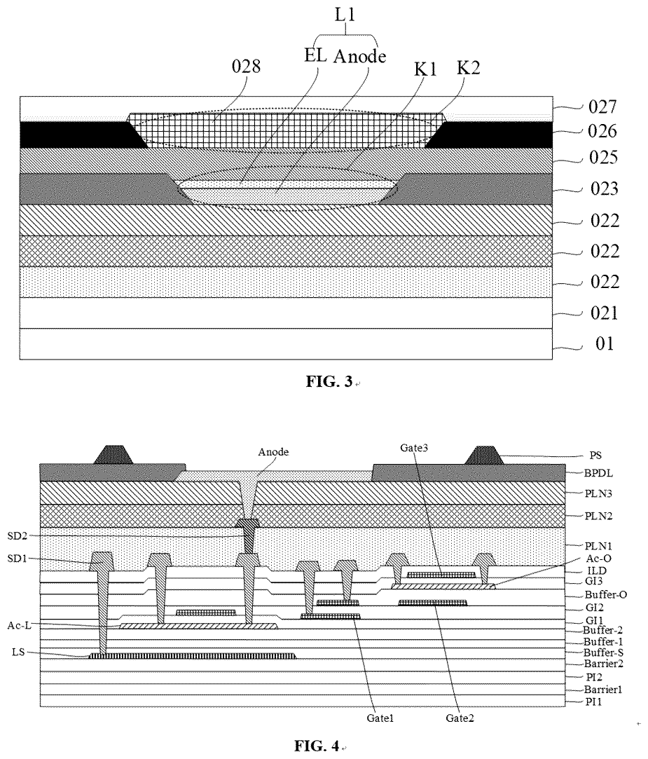

On the basis of FIG. 2, FIG. 3 shows a sectional view of another display panel. As shown in FIG. 3, the display panel described in the embodiment of the present disclosure may also include: an encapsulation layer 025, a black matrix (BM) layer 026 and an overcoat (OC) layer 027 that are located on one side of the BPDL 023 away from the substrate 01 and sequentially stacked in a direction away from the substrate 01. The PS layer 024 is not shown in FIG. 3. Optionally, the encapsulation layer 025 may be a thin film encapsulation (TFE) layer, that is, a thin film encapsulation can be used. A material for the OC layer may be an organic material, that is, the OC layer may be an organic OC layer.

The BM layer 026 may have a plurality of second openings K2 that is in a one-to-one correspondence with the plurality of first openings K1. That is, the plurality of second openings K2 may also be arranged at intervals in a direction parallel to the bearing surface of the substrate 01. FIG. 3 also only schematically shows one second opening K2 corresponding to one first opening K1.

The display panel may also include a filter layer 028 located in each second opening K2. In other words, the filter layers 028 located in different second openings K2 can be separated by the BM layer 026. Optionally, each filter layer 028 may include a color filter (CF). Of course, in some other embodiments, the filter layer 028 may also include a color barrier, which will not be limited in the embodiment of the present disclosure.

In addition, in the embodiment of the present disclosure, a color of the filter layer in each second opening K2 is the same as a color of the light-emitting element L1 in the corresponding first opening K1. For example, if a light-emitting element L1 in a first opening K1 is a red light-emitting element L1, the filter layer 028 in the second opening K2 corresponding to the first opening K1 may also be red.

In addition, optionally, in the embodiment of the present disclosure, the colors of the light-emitting elements L1 located in adjacent first openings K1 may be different, and correspondingly, the colors of the filter layers 028 located in adjacent second openings K2 may also be different. Here, the color of the light-emitting element L1 may refer to a color of light emitted by the light-emitting element L1. For example, the display panel may include a plurality of red light-emitting elements, a plurality of green light-emitting elements and a plurality of blue light-emitting elements in a total of three colors. In each three adjacent first openings K1, the red light-emitting element, the green light-emitting element and the blue light-emitting element may be arranged sequentially. Of course, in some other embodiments, the colors of the light-emitting elements L1 located in the adjacent first openings K1 may also be the same. The arrangement of the plurality of light-emitting elements L1 is not limited in the embodiment of the present disclosure.

Also, in the embodiment of the present disclosure, a pixel circuit formed by the pixel circuit layer 021 may be electrically connected to the light-emitting element L1 through a via hole running through the plurality of PLN layers 022, and the pixel circuit is used to drive the light-emitting element L1 to emit light. For example, if the light-emitting element L1 is an organic light-emitting diode (OLED), the pixel circuit may transmit a driving current to the light-emitting element L1, thereby driving the light-emitting element L1 to emit light. The light emitted by the light-emitting element L1 may be filtered by the filter layer 028 and then emitted, so that the display panel may display a picture. Since there is no need to arrange a polarizer, the display panel may be the COE panel described in the above embodiment.

In addition, continuing with reference to FIG. 3, it can also be seen that the light-emitting element L1 in the embodiment of the present disclosure may include an anode and an electro luminescence (EL) layer that are sequentially stacked in a direction away from the substrate 01. The electrical connection between the pixel circuit formed by the pixel circuit layer 021 and the light-emitting element L1 may refer to: the electrical connection between the pixel circuit and the anode included in the light-emitting element L1. Of course, the light-emitting element L1 may also generally include a cathode (not shown in the drawings) located on one side of the EL layer away from the substrate 01. The pixel circuit formed by the pixel circuit layer 02 may transmit a light-emitting driving signal to the anode included in the light-emitting element L1. The cathode included in the light-emitting element L1 may be electrically connected to a power supply terminal and receive a power supply signal transmitted by the power supply terminal. The EL layer included in the light-emitting element L1 may emit light under the effect of a voltage difference between the light-emitting driving signal received by the anode and the power supply signal received by the cathode.

Taking the structures shown in FIG. 2 and FIG. 3 as examples, FIG. 4 shows a schematic structural diagram of another display panel. Referring to FIG. 4, it can be seen that the pixel circuit layer 021 may include: an active layer Ac, a gate metal layer Gate and a source-drain metal layer SD that are sequentially stacked in a direction away from the substrate 01.

Optionally, FIG. 4 shows a total of two transistors of an N-type transistor and a P-type transistor. formed by the pixel circuit layer 021. Materials for the active layer of the P-type transistor may include a low-temperature polysilicon material. Materials for the active layer of the N-type transistor may include an oxide material. In the drawings, for a distinguishing purpose, the active layer Ac of the P-type transistor is labeled as Ac-L, and the active layer Ac of the N-type transistor is labeled as Ac-O. The active layer Ac-O is farther away from the substrate 01 than the active layer Ac-L.

In addition, it can be seen from FIG. 4 that the pixel circuit as shown includes three gate metal layers (Gate1, Gate2, and Gate3) that are sequentially stacked in a direction away from the substrate 01. The source-drain metal layer SD includes two source-drain metal layers (SD1 and SD2) that are sequentially stacked in a direction away from the substrate 01. In addition, the pixel circuit further includes three PLN layers (PLN1, PLN2, and PLN3) that are sequentially stacked in a direction away from substrate 01.

The PLN layer PLN1 is located between the SD1 and the SD2, and the SD2 is located between the PLN1 and the PLN2. In addition, the SD2 is lapped with the SD1 through a via bole running through the PLN1. The anode of the light-emitting element L1 is lapped with the SD2 through a via hole running through the PLN3 and the PLN2, and is thus indirectly lapped with the SD1, so that the electrical connection between the pixel circuit and the light-emitting element L1 is realized.

In addition, referring to FIG. 4, it can also be seen that the display panel may further include: a light shielding layer LS and three buffer layers (labeled as Buffer-S, Buffer-1 and Buffer-2, respectively), that are located between the substrate 01 and the active layer Ac-L and sequentially stacked in a direction away from the substrate 01; a gate insulator (GI) layer GI1. located between the Ac-L and the Gate1; a GI layer GI2, located between the Gate1 and the Gate2; a buffer layer buffer-O located between the Gate2 and the Ac-O; a GI layer GI3, located between the Ac-O and the Gate3; and an inter level dielectric (ILD) layer, located between the Gate3 and the SD1. In addition, the SD1 is also lapped with the LS layer, the Ac-L, the Ac-O, the Gate1 and the Gate2, respectively. The Gate1 and the Gate2 that are lapped with the SD1 are used to form a storage capacitor Cst in the pixel circuit. In addition, the substrate 01 may include a base PI1, a barrier layer Barrier1, a base PI2 and a barrier layer Barrier2 that are sequentially stacked in a direction close to the LS layer.

Optionally, the base PI1 and the base PI2 may be a flexible base, and materials for the flexible substrate may include polyimide (PI). Of course. in some other embodiments. the substrate 01 may also be a non-flexible substrate, such as glass. Materials for the Barrier1, the Barrier2, the buffer layer and the ILD layer may include silicon oxide (SiO2) or silicon nitride (SiNx). Also, materials for the PLN layer may include PI. It should be noted that the examples of the materials here are schematic descriptions only.

Optionally, among the plurality of barrier dams 03 described in the embodiments of the present disclosure, the barrier dam 03 close to the display region AA may have a width less than that of the barrier dam 03 away from the display region AA: and/or the barrier dam 03 close to the display region AA may have a height less than that of the barrier dam 03 away from the display region AA. This refers to being the closest to the display region AA and the furthest from the display region AA, which are described similarly in following embodiments and will not be repeated one by one.

For example, if two barrier dams 03 are included, the barrier dam 03 closest to the display region AA and the barrier dam 03 furthest from the display region AA refer to these two barrier dams 03, respectively. If more than three barrier dams 03 are included, the width of each barrier dam 03 between the barrier dam 03 closest to the display region AA and the barrier dam 03 furthest away from the display region AA may be equal to, less than, or greater than that of the barrier dam 03 closest to the display region AA or the barrier dam 03 furthest away from the display region AA. The thickness is the same and will not be repeated. That is, the width and height of each barrier dam 03 between the barrier dam 03 closest to the display region AA and the barrier dam 03 furthest from the display region AA are not limited in the embodiments of the present disclosure. Of course, in some other embodiments, the width of the barrier dam 03 close to the display region AA may also be greater than that of the barrier dam 03 away from the display region AA, and the height of the barrier dam 03 close to the display region AA may also be greater than that of the barrier dam 03 away from the display region AA.

It should be noted that a direction of the width described in the embodiment of the present disclosure may be parallel to the bearing surface of the substrate 01, and a direction of the height may be perpendicular to the bearing surface of the substrate 01, which will not be explained one by one in the following embodiments.

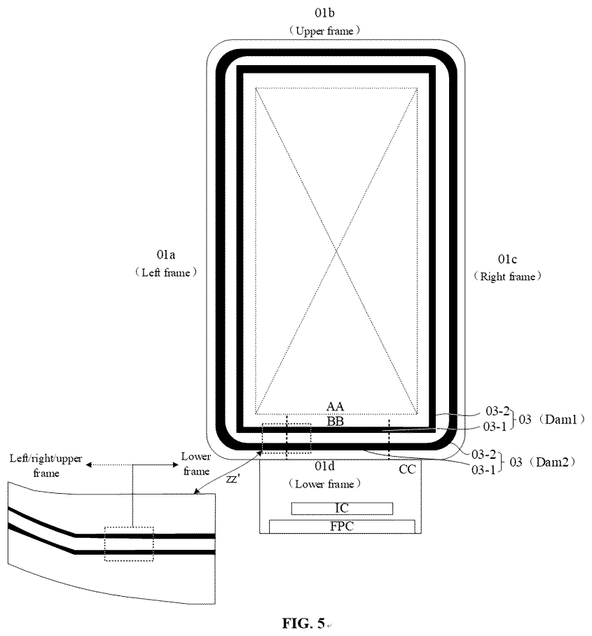

Exemplarily, FIG. 5 is a schematic structural diagram of yet another display panel provided by an embodiment of the present disclosure. The display panel as shown includes two barrier dams 03 of a first barrier dam 03 and a second barrier dam 03, that are arranged at intervals in a direction away from a display region AA. For a distinguishing purpose, the barrier dam 03 close to the display region AA is labeled as dam1; and the barrier dam 03 away from the display region AA is labeled as dam2.

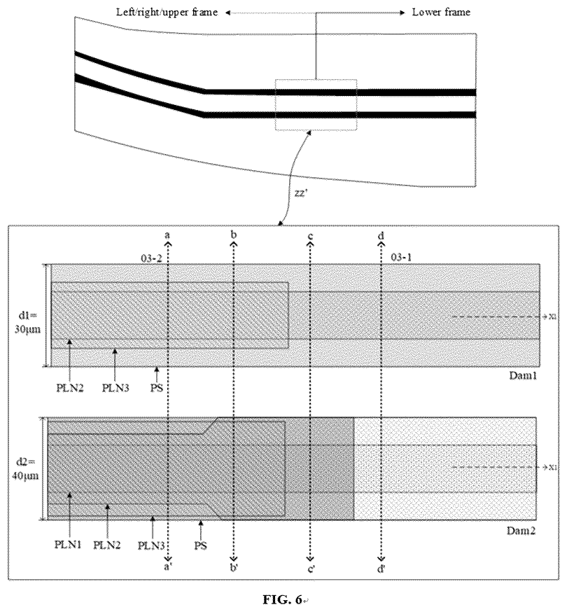

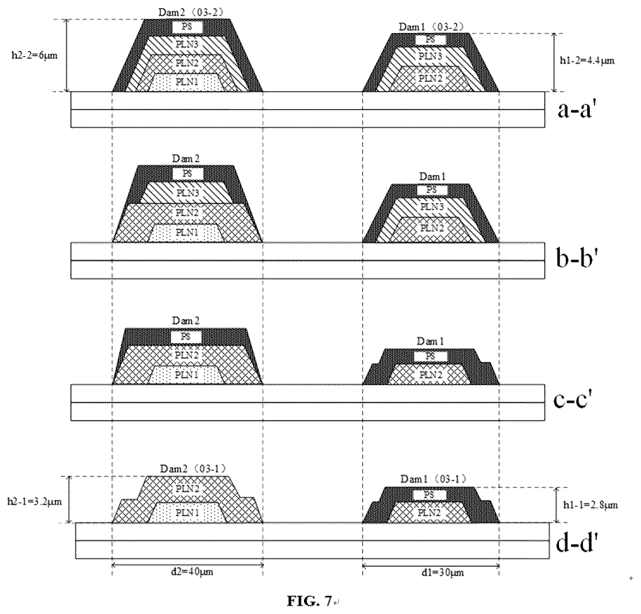

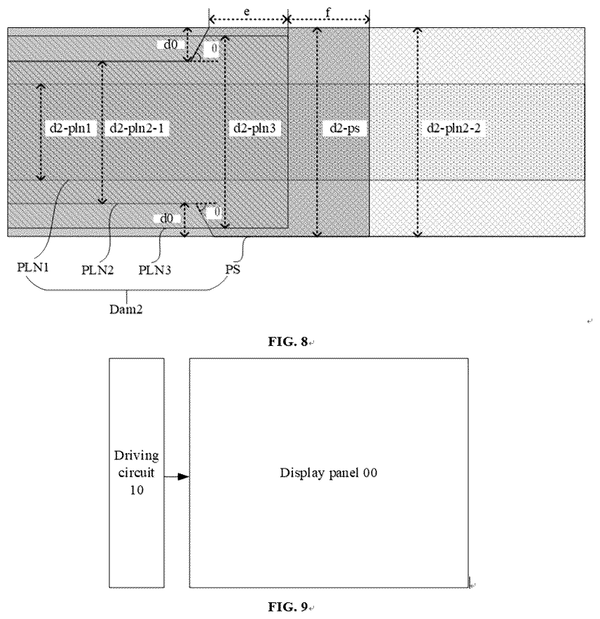

On the basis of FIG. 5, FIG. 6 shows a top view of the Barrier dam1 and the Barrier dam2 in a zz′ zone shown in FIG. 5. FIG. 7 shows a sectional view of the top view shown in FIG. 6 in four directions of a-a′, b-b′, c-c′ and d-d′. FIG. 8 shows a partially enlarged top view of the Barrier dam2 in the structure shown in FIG. 6.

Combined with FIG. 5 and FIG. 7, it can be seen that a width dl of the Barrier dam1 as shown may be 30 micrometers (μm), and a width d2 of the Barrier dam2 may be 40 μm. Of course, the width here is only a schematic description, and the width of each barrier dam 03 may generally be between 30 μm and 40 μm. A maximum height h1 of the Barrier dam1 may be 4.4 μm, and a maximum height h2 of the Barrier dam2 may be 6 μm. Of course, the height here is only a schematic description.

Optionally, continuing to combine with FIG. 5, it can be seen that a plurality of barrier dams 03 surrounding one side of the display region AA may be concentric, that is, the plurality of barrier dams 03 may surround one side of the display region AA at equal intervals. In other words, spacing between each two adjacent barrier dams 03 may be fixed. In this way, the barrier reliability can be improved.

Optionally, continuing with reference to FIG. 5, it can be seen that the substrate 01 described in the embodiment of the present disclosure may also have a binding region CC that is located on one side of the non-display region BB away from the display region AA and adjacent to the non-display region BB.

In each barrier dam 03, a height of the first portion 03-1 close to the binding region CC may be less than that of the second portion 03-2 away from the binding region.

For example, referring to FIG. 5, the substrate 01 as shown is rectangular, i.e., the substrate 01 may have a first frame 01a, a second frame 01b, a third frame 01c, and a fourth frame 01d. In FIG. S, the first frame 01a refers to a left frame, the second frame 01b refers to an upper frame, the third frame 01c refers to a right frame, and the fourth frame 0-d refers to a lower frame. In this case, the positions of the frames are only described schematically, and are not limited. For example, in some other embodiments, the first frame 01a may also refer to a right frame, and the third frame 01c may refer to a left frame. In addition, the shape of the substrate 01 is only described schematically here, and is not limited. For example, in some other embodiments, the substrate 01 may also be in other shapes, such as a trapezoidal shape.

On the basis of FIG. 5 and in conjunction with FIG. 1, in the embodiment of the present disclosure, the non-display region BB may surround the display region AA, and the binding region CC may be located on one side of the fourth frame 01d. That is. the binding region CC may be located on a side where the lower frame of the rectangular substrate 01 shown in FIG. 5 is located. In addition, each barrier dam 03 located in the non-display region BB may surround the display region AA. On this basis, it can be seen that in each barrier dam 03, the first portion 03-1 may be located on one side of the fourth frame 01d; the second portion 03-2 may be located on one side of the first frame 01a, the second frame 01b, the third frame 01c and the fourth frame 01d; and a part of the second portion 03-2 that is located on one side of the fourth frame 01d is located outside the first portion 03-1. That is, the first portion 03-1 may be located on the side where the lower frame is located, most of the second part 03-2 may be located on the side where the left, right and upper frames are located, and a small part of the second part 03-2 may be located on the side where the lower frame is located. and the small part on the side where the lower frame is located may be connected with the first portion 03-1. which is only on the side where the lower frame is located, and they do not overlap with each other. In other words, the first portion 03-1, which is located on the side where the lower frame is located, is closer to the binding portion CC than the second portion 03-2, which is located on the side where the lower frame is located. Because only a small part of the second portion 03-2 is located on the side where the lower frame is located, the following embodiments are described by taking the second portion 03-2 being located on the sides where the left, right and upper frames are located as an example. Also, in each barrier dam 03, a height of a part located on the side where the lower frame is located may be less than that of a part located on the sides where the left, right and upper frames are located

It should be noted that, combined with FIG. 5 and FIG. 6, it can be seen that FIG. 6 shows the top view of the Barrier dam1 and the Barrier dam2 in the zz′ zone on the left side of the lower frame in FIG. 5. for the symmetrical positions of the right side of the lower frame in FIG. 5 in relation to this left zz′ zone, the Barrier dam1 and the Barrier dam2 are designed in the same way and will not be repeated.

It should also be noted that as can be seen in FIG. 5, a flexible printed circuit (FPC) and an integrated circuit (IC) may be bound in the binding region CC. The pixel structure 02 may be electrically connected to a circuit in the binding region CC through a signal line to receive a driving signal. For example, the signal line may be a flexible multi-layer on cell (FMLOC) metal signal line. Correspondingly, it can be seen that the FMLOC located in the binding region CC needs to cross the barrier dam in the adjacent non-display region BB to extend to the display region AA. Therefore, it is possible to facilitate the crossing of the line by setting the height of the first portion 03-1 close to the binding region CC in the barrier dam 03 to be less than the height of the second portion 03-2 away from the binding region. In general, the height of the first portion 03-1 does not exceed 4 μm. FMLOC is a metal signal line in a display apparatus with a touch-display integrated structure. The display apparatus with the touch-display integrated structure generally includes a touch structure and a display panel. The FPC may be electrically connected to the touch structure and the display panel to control a touch structure to achieve a touch function, and to control the display panel to display an image.

For example. continuing to combine FIG. 5 and FIG. 7, it can be seen that the height h1-1 of the first portion 03-1 of the Barrier dam1 as shown may be 2.8 μm, and the height h1-2 of the second portion 03-2 may be 4.4 μm. The height h2-1 of the first portion 03-1 of the Barrier dam2 may be 3.2 μm, and the height h2-2 of the second portion 03-2 may be 6 μm. From this example, it can also be seen that the height of any portion of the Barrier dam1 close to the display region AA may be less than that of any portion of the Barrier dam2 away from the display region AA.

Optionally. in conjunction with FIG. 6 and FIG. 7, it can be seen that in each barrier dam 03 described in the embodiment of the present disclosure, the widths of the plurality of barrier film layers 031 included in the first portion 03-1 and the widths d2 of the plurality of barrier film layers 031 included in the second portion 03-2 may all decrease sequentially in a direction close to the substrate 01. In addition, in each two adjacent barrier film layers 031, an orthographic projection of the barrier film layer 031 away from the substrate 01 on the substrate 01 may cover an orthographic projection of the barrier film layer 031 close to the substrate 01 on the substrate 01. In other words, a design of enclosing the lower part with the upper part may be adopted for the barrier film layers. On this basis, it can be seen that among the plurality of barrier film layers 031 included in the barrier dam 03, the width of the barrier film layer 031 on one side furthest away from the substrate 01 (i.e., the uppermost barrier film layer 031) is the width of the barrier dam 03. By adopting the design of enclosing the lower part with the upper part for the film layers, the slope of the formed barrier dam 03 can be prevented from being too large, which is beneficial to the uniformity of the subsequent film formation on one side of the barrier dam 03 away from the substrate 01.

Optionally, referring to FIG. 6, it can also be seen that, in each barrier dam 03 (e.g., Barrier dam1 and Barrier dam2), central axes of the plurality of barrier film layers 031 included in the first portion 03-1 may be collinear, central axes of the plurality of barrier film layers 031 included in the second portion 03-2 may be collinear, and a central axis x1 of the first portion 03-1 may be collinear with a central axis of the second portion 03-2. In the drawing, the central axes are uniformly labeled as x1. In this way, spacing between the adjacent sides of each two adjacent barrier film layers 031 may be equal, which is convenient for layout design.

It should be noted that the central axis here refers to a central axis of a part of the barrier dam 03 that is located on one side of each frame, but does not include a part of the barrier dam 03 located at a corner of the substrate 01 shown in FIG. 5. The corner shown in FIG. 5 includes: a corner between the upper frame and the left frame, a corner between the upper frame and the right frame, a corner between the lower frame and the left frame, and a corner between the lower frame and the right frame. In addition, each corner may be a rounded corner shown in FIG. 5. Of course, in some other embodiments, the corner may also be shaped as a right angle or in other shape. The shapes of the corners are not limited in the embodiments of the present disclosure.

Optionally, in the embodiment of the present disclosure, the number of barrier film layers 031 included in the first portion 03-1 in each barrier dam 03 may be less than that of barrier film layers 031 included in the second portion 03-2. In this way, the height of the first portion 03-1 may be less than that of the second portion 03-2. Of course, in some other embodiments, it is also possible to set the number of barrier film layers 031 included in the first portion 03-1 to be equal to the number of barrier film layers 031 included in the second portion 03-2, and to adjust the thickness of at least part of the barrier film layers 031 so that the height of the first portion 03-1 is less than that of the second portion 03-2.

For example, referring to FIG. 6 and FIG. 7, in the Barrier dam1 as shown, the first portion 031-1 may include two barrier film layers 031, and the second portion 031-2 may include three barrier film layers 031. In the Barrier dam2, the first portion 031-1 includes two barrier film layers 031, and the second portion 03-2 may include four barrier film layers 031.

Optionally, in the embodiment of the present disclosure, in each barrier dam 03, the plurality of barrier film layers 031 included in the first portion 03-1 may belong to barrier film layers 031 among the plurality of barrier film layers 031 included in the second portion 03-2. Also, in a part of barrier dams 03 among the plurality of barrier dams 03, the barrier film layer 031 away from the substrate 01 among the plurality of barrier film layers 031 included in the first portion 03-1 is the same as the barrier film layer 031 away from the substrate 01 among the plurality of barrier film layers 031 included in the second portion 03-2. In the other part of the barrier dams 03, the barrier film layer 031 away from the substrate 01 among the plurality of barrier film layers 031 included in the first portion 03-1 is different from the barrier film layer 031 away from the substrate 01 among the plurality of barrier film layers 031 included in the second portion 03-2.

For example, referring to FIG. 2 to FIG. 4, the pixel structure 02 described in the embodiment of the present disclosure may include a first PLN layer PLN1, a second PLN layer PLN2 and a third PLN layer PLN3 that are sequentially stacked in a direction away from the substrate 01. On this basis, continuing with reference to FIG. 6 and FIG. 7, it can be seen that in the Barrier dam1, the two barrier film layers 031 included in the first portion 03-1 may be located on the same layer as the PLN2 and a PS layer, respectively; and the three barrier film layers 031 included in the second portion 03-2 may be located on the same layer as the PLN2, the PLN3 and the PS layer, respectively. In the Dam2, the two barrier film layers 031 included in the first portion 03-1 are located on the same layer as the PLN1 and the PLN2, respectively; and the four barrier film layers 031 included in the second portion 03-2 are located on the same layer as the PLN1, the PLN2, the PLN3 and the PS layer, respectively. It can thus be seen that the barrier film layers 031 of the first portion 03-1 and the second portion 03-2 in the Barrier dam1 away from the substrate 01 are the same and are both PS layers, while the barrier film layers 031 of the first portion 03-1 and the second portion 03-2 in the Barrier dam2 away from the substrate 01 are different and the barrier film layers 031 are the PS layer and the PLN2, respectively.

That is to say, for the left/right/upper frame, Barrier dam1 which is close to the display region AA may use three film layers of PLN2+PLN3+PS to be stacked, and the height h1-2 as described in the above embodiment may be 4.4 μm. The Barrier dam2 which is away from the display region AA may use four film layers of PLN1+PLN2+PLN3+PS to be stacked, and the height h2-2 as described in the above embodiment may be 6 μm. For the lower frame near an IC side, the Barrier dam1 which is close to the display region AA may use two film layers of PLN2+PS to be stacked, and the height h1-1 may be 2.8 μm as recorded in the above embodiment. The Barrier dam2 which is away from the display region AA may use two film layers of PLN1+PLN2 to be stacked, and the height h2-1 as described in the above embodiment may be 3.2 μm.

It should be noted that the film layer stacking mode of the above barrier dam 03 is only a schematic description. In some embodiments, the Barrier dam1 and the Barrier dam2 may also be formed by stacking other film layers in the pixel structure 02. Also, the above heights are only schematic descriptions. In the case of the PLN layer 022, its height (which may also refer to the thickness) is generally between 1.5 μm and 1.6 μm. In the case of the PS layer 024, its height is generally between 1.2 μm and 1.5 μm. On this basis, the heights of the PLN layer 022 and the PS layer 024 may be flexibly set to flexibly adjust the heights of the Barrier dam1 and the Barrier dam2. In addition, in the above embodiment, the widths of the Barrier dam1 and the Barrier dam2 are only schematic descriptions.

For example, for the Barrier dam2 at the left/right/upper frame, the heights of the PLN1, the PLN2, the PLN3 and the PS layer included in the Barrier dam2 may be 1.6 μm, 1.6 μm, 1.6 μm and 1.2 μm, respectively. Correspondingly, their total height h2-2 as described in the above embodiment is 6 μm. The widths of the PLN1, the PLN2, the PLN3 and the PS layer included in the Barrier dam2 may be 18 μm, 28 μm, 36 μm and 40 μm, respectively. Correspondingly, a maximum width of the Barrier dam2 is the width of the PS layer 024, i.e., 40 μm.

Optionally, in combination with FIG. 6 to FIG. 8, it can be seen that if the widths of the plurality of barrier film layers 031 included in the first portion 03-1 and the widths of the plurality of barrier film layers 031 included in the second portion 03-2 in the barrier dam 023 all decrease sequentially in a direction close to the substrate 01, that is, the film layers are designed to be enclose the lower side with the upper side; and the plurality of barrier film layers 031 included in the first portion 03-1 belongs to the barrier film layers 031 among the plurality of barrier film layers 031 included in the second portion 03-2, for each barrier dam 03 in the other part of the barrier dams 03, the barrier dam 03 (for example, Barrier dam2) may also include a transition region located between the first portion 03-1 and the second portion 03-2, which may refer to a region between a-a′ and d-d′ shown in FIG. 6.

In the transition region, among the plurality of barrier film layers included in the second portion 03-2, a target film layer may be transitionally widened to be equal to the width of the barrier dam 03. The target film layer among the plurality of barrier film layers included in the second portion 03-2 is used as the barrier film layer away from the substrate 01 among the plurality of barrier film layers included in the first portion 03-1. For example, the target film layer shown in FIGS. 6 to 8 is the PLN2 included in the Barrier dam2.

In addition, among the plurality of barrier film layers included in the second portion, an orthographic projection of the barrier film layer away from the substrate 01 on the substrate 01 covers an orthographic projection of the transition region on the substrate 01. For example, the barrier film layer in the second portion of the Barrier dam2 shown in FIGS. 6 to 8 away from the substrate 01 is the PS layer 024. In this way, combined with FIG. 7, the widths of the barrier dam 03 at various positions can be reliably guaranteed to be consistent on the basis of the replacement of top film layers of the first portion 03-1 and the second portion 03-2. In addition, process influences are also taken into account.

Optionally, in conjunction with FIG. 8, for various sides of the target film layer in the transition region, the widening angles θ may be the same and all may be less than 90 degrees, and/or increased widths do may be the same. In this way, the process feasibility may be mainly considered to ensure that the uniformity of increased widths of the upper and lower sides may be better.

For example, combined with FIG. 6 to FIG. 8, it can be seen that the top barrier film layers of the first portion 03-1 and the second portion 03-2 of the Barrier dam1 are both PS layers 024, and the width of the PS layer 024 is the width of the barrier dam 03 on the basis of the design of enclosing the lower side with the upper side, so the width of the Barrier dam1 at each frame can be made to be consistent without widening. Because the top barrier film layer of the first portion 03-1 of the Barrier dam2 is replaced by the PLN2 from the top barrier film layer (the PS layer 024) of the second portion 03-2, while the width of the PLN2 is less than the width of the PS layer 024, so the PLN2 needs to be widened in the transition region, so that the width of the PLN2 in the first part 03-1 may be widened to be equal to the width of the top barrier film layer (the PS layer 024) of the second portion 03-2. At the same time, in the transition region, the PS layer 024 may also be extended for cover, thereby ensuring that the widths of the Barrier dam2 at various positions are equal.

Optionally, in the Barrier dam2 shown in FIG. 8, the width of the PLN1 is labeled as d2-pln1, widths of the PLN2 before and after the widening are labeled as d2-pln2-1 and d2-pln2-2 respectively, the width of the PLN3 is labeled as d2-pln3, the width of the PS layer is labeled as d2-ps, an widening angle and an increased width are also labeled as θ and do respectively, and spacing e between an end boundary of the PLN3 and an initial boundary of the widened PLN2 and spacing f between an end boundary of the PS layer and an end boundary of the PLN3 are also labeled. In one embodiment, d2-pln1 as described in the above embodiment may be 18 μm. d2-pln2-1 may be 28 μm. d2-pln3 may be 36 μm. d2-pln2-2 and d2-ps may be 40 μm. e may be 20 μm. f may be 20 μm. θ may be 45 degrees. Also, d0 may be 6 μm. That is, the upper and lower sides of the PLN2 may be widened by 6 μm in a direction of 45 degrees each, for a total of 12 μm, so as to achieve reliable widening from 28 μm to 40 μm. It can also be seen from this embodiment that the PLN3 may also cover a part of the transition region, so that the widths of the Barrier dam2 at various positions can be further reliably ensured to be consistent. Of course, the widths and the included angles here are only schematic descriptions, and do not limit the barrier dam structure in the embodiments of the present disclosure

In summary, an embodiment of the present disclosure provides a display panel. The display panel includes a substrate, a pixel structure located on a display region of the substrate, and a barrier dam located in a non-display region of the substrate. The pixel structure includes a pixel circuit layer, at least one PLN layer, a BPDL and a PS layer that are sequentially stacked. The barrier dam includes a plurality of barrier film layers. The plurality of barrier film layers is located on the same layer as a part of film layers in the PLN layers and the PS layer included in the pixel structure. That is, the barrier dam may be prepared by using the PLN layers and the PS layer that have a good bending performance, without using the BPDL having a poor bending performance. In this way, the problem that the BPDL cannot be applied to the preparation of barrier dams in folded products due to the poor bending performance can be solved. The barrier dam in the display panel provided by the embodiment of the present disclosure may be well applied to different types of display products.

FIG. 9 is a schematic structural diagram of a display apparatus according to an embodiment of the present disclosure. As shown in FIG. 9, this display apparatus includes: a driving circuit 10 and a display panel 00 as described in the above embodiment.

The driving circuit 10 is electrically connected to the display panel 00 and is configured to drive the display panel 00 to emit light.

Optionally, the display apparatus provided by the embodiment of the present disclosure may be any product or component having a display function, such as an OLED display apparatus, a mobile phone, a tablet computer, a flexible display apparatus, a television and a display.

It should be noted that in the accompanying drawings, for clarity of the illustration, the dimension of the layers and regions may be scaled up. It may be understood that when an element or layer is described as being “above” another element or layer, the described element or layer may be directly on the other element or layer, or at least one intermediate layer may be arranged between the described element or layer and the other element or layer. In addition, it may be understood that when an element or layer is described as being “below” another element or layer, the described element or layer may be directly below the other element or layer, or at least one intermediate layer may be arranged between the described element or layer and the other element or laver. In addition, it may be further understood that when a layer or element is described as being arranged “between” two layers or elements, the described layer or element may be the only layer between the two lavers or elements, or at least one intermediate layer or element may be arranged between the described element or layer and the two layers or elements. In the whole specification described above, like reference numerals denote like elements.

Also, the terms used in the embodiments of the present disclosure are for the purpose of explaining the embodiments only and are not intended to limit the present disclosure. The technical and scientific terms as used in the implementations of the present disclosure should have the meanings as commonly understood by a person of ordinary skill in the art of the present disclosure, unless otherwise defined.

For example, in the embodiments of the present disclosure, the terms “first” and “second” are used for descriptive purposes only and are not to be construed as indicating or implying relative importance. The term “plurality” refers to two or more, unless specifically defined otherwise.

Similarly, words such as “a” or “one” do not denote a quantitative limit, but rather the existence of at least one.

The word “include”, “comprise” or similar terms mean that elements or objects appearing before the term “include” or “comprise” cover the listed elements or objects and its equivalents appearing after the term “include” or “comprise”, while other elements or objects are not excluded.

“Upper”, “lower”, “left”, “right” and the like are only used to indicate the relative positional relationship, and when the absolute position of a described object changes, the relative positional relationship may also change accordingly.

“And/or” indicates that there may be three relationships, for example, A and/or B may indicate: A exists alone, A and B exist at the same time, and B exists alone. The character “/” generally indicates an “or” relationship between the contextual objects.

The foregoing descriptions are merely optional embodiments of the present disclosure, and are not intended to limit the present disclosure. Within the spirit and principles of the present disclosure, any modifications, equivalent substitutions, improvements, etc., should be within the protection scope of the present disclosure.

1. A display panel, comprising:
a substrate, having a display region and a non-display region that at least partially surrounds the display region;
a plurality of pixel structures, wherein the plurality of pixel structures is located on one side of the substrate and in the display region, each pixel structure comprises a pixel circuit layer, at least one planarization (PLN) layer, a black pixel definition layer (BPDL) and a photo spacer (PS) layer that are sequentially stacked in a direction away from the substrate, the BPDL has a plurality of first openings arranged at intervals along a bearing surface parallel to the substrate, and each pixel structure further comprises a light-emitting element located in each first opening; and
a plurality of barrier dams, wherein the plurality of barrier dams is located on one side of the substrate and in the non-display region, the plurality of barrier dams is arranged at intervals in a direction away from the display region, each barrier dam comprises a plurality of barrier film layers sequentially stacked in a direction away from the substrate, and the plurality of barrier film layers is located on a same layer as a part of film layers in the at least one PLN layer and the PS layer.

2. The display panel according to claim 1, wherein, among the plurality of barrier dams, a barrier dam close to the display region has a width less than that of a barrier dam away from the display region; and
wherein a direction of the width is parallel to the bearing surface of the substrate, and a direction of the height is perpendicular to the bearing surface of the substrate.

3. The display panel according to claim 1, wherein the substrate also has a binding region that is located on one side of the non-display region away from the display region and is adjacent to the non-display region; and
in each of the plurality of barrier dams, a first portion close to the binding region has a height less than that of a second portion away from the binding region.

4. The display panel according to claim 3, wherein the substrate is rectangular and has a first frame, a second frame, a third frame and a fourth frame;
the non-display region surrounds the display region, and each of the plurality of barrier dams located in the non-display region surrounds the display region; and the binding region is located on one side of the fourth frame; and
in each of the plurality of barrier dams, the first portion is located on one side of the fourth frame, the second portion is located on one side of the first frame, the second frame, the third frame and the fourth frame, and a part of the second portion that is located on one side of the fourth frame is located outside the first portion.

5. The display panel according to claim 3, wherein widths of the plurality of barrier film layers comprised in the first portion and widths of the plurality of barrier film layers comprised in the second portion decrease sequentially in a direction close to the substrate, respectively; and, in each two adjacent barrier film layers, an orthographic projection of one barrier film layer away from the substrate on the substrate covers an orthographic projection of one barrier film layer close to the substrate on the substrate.

6. The display panel according to claim 5, wherein central axes of the plurality of barrier film layers comprised in the first portion are collinear, central axes of the plurality of barrier film layers comprised in the second portion are collinear, and the central axes of the first portion are collinear with the central axes of the second portion.

7. The display panel according to claim 3, wherein a number of the barrier film layers comprised in the first portion is less than a number of the barrier film layers comprised in the second portion.

8. The display panel according to claim 7, wherein the plurality of barrier film layers comprised in the first portion belongs to the barrier film layers among the plurality of barrier film layers comprised in the second portion.

9. The display panel according to claim 3, wherein, in a part of barrier dams among the plurality of barrier dams, a barrier film layer away from the substrate among the plurality of barrier film layers comprised in the first portion is the same as a barrier film layer away from the substrate among the plurality of barrier film layers comprised in the second portion; and in other part of the barrier dams, a barrier film layer away from the substrate among the plurality of barrier film layers comprised in the first portion is different from a barrier film layer away from the substrate among the plurality of barrier film layers comprised in the second portion.

10. The display panel according to claim 9, wherein if the widths of the plurality of barrier film layers comprised in the first portion and the widths of the plurality of barrier film layers comprised in the second portion all decrease sequentially in a direction close to the substrate, respectively, and the plurality of barrier film layers comprised in the first portion belongs to the barrier film layers among the plurality of barrier film layers comprised in the second portion, for each of the other part of the barrier dams, the barrier dam further comprises a transition region between the first portion and the second portion;
in the transition region, among the plurality of barrier film layers comprised in the second portion, a target film layer is transitionally widened to be equal to a width of the barrier dam, and the target film layer is used as a barrier film layer, away from the substrate, among the plurality of barrier film layers comprised in the first portion; and
among the plurality of barrier film layers comprised in the second portion, an orthographic projection of a barrier film layer away from the substrate on the substrate covers an orthographic projection of the transition region on the substrate.

11. The display panel according to claim 10, wherein, for various sides of the target film layer in the transition region, widening angles are the same and all less than 90 degrees.

12. The display panel according to claim 3, comprising a first barrier dam and a second barrier dam which are arranged at intervals in a direction away from the display region, wherein
in the first barrier dam, the first portion comprises two barrier film layers and the second portion comprises three barrier film layers; and
in the second barrier dam, the first portion comprises two barrier film layers and the second portion comprises four barrier film layers.

13. The display panel according to claim 12, wherein the pixel structure comprises a first PLN layer, a second PLN layer and a third PLN layer that are successively stacked in a direction away from the substrate;
in the first barrier dam, two barrier film layers comprised in the first portion are located on a same layer as the second PLN layer and the PS layer, respectively; three barrier film layers comprised in the second portion are located on a same layer as the second PLN layer, the third PLN layer and the PS layer, respectively; and
in the second barrier dam, two barrier film layers comprised in the first portion are located on a same layer as the first PLN layer and the second PLN layer, respectively; four barrier film layers comprised in the second portion are located on a same layer as the first PLN layer, the second PLN layer, the third PLN layer and the PS layer, respectively.

14. The display panel according to claim 1, further comprising:
an encapsulation layer, a black matrix (BM) layer and an overcoat layer that are located on one side of the BPDL away from the substrate and are sequentially stacked in a direction away from the substrate, wherein the BM layer has a plurality of second openings that is in a one-to-one correspondence with the plurality of first openings; and
a filter layer, wherein the filter layer is located in each of the second openings, and a color of the filter layer in each second opening is the same as that of the light-emitting element in a corresponding first opening.

15. A display apparatus, comprising a driving circuit and the display panel according to claim 1; and
wherein the driving circuit is electrically connected to the display panel and is configured to drive the display panel to emit light.

16. The display panel according to claim 1, wherein, among the plurality of barrier dams, the barrier dam close to the display region has a height less than that of the barrier dam away from the display region.

17. The display panel according to claim 10, wherein, for various sides of the target film layer in the transition region, increased widths are the same.
